(19) United States
(12) Patent Application Publication
(10) Pub. No.: US 2020/0105324 A1
(43) Pub. Date: Apr. 2, 2020

(54) MULTI-MAGNET STABILIZED SPIN ORBIT TORQUE MRAM

(71) Applicant: INTEL CORPORATION, Santa Clara, CA (US)

(72) Inventors: Angeline Smith, Hillsboro, OR (US); Sasikanth Manipatruni, Portland, OR (US); MD Tofizur Rahman, Portland, OR (US); Noriyuki Sato, Hillsboro, OR (US); Tanay Gasovi, Hillsboro, OR (US); Christopher Wiegand, Portland, OR (US); Ian Young, Portland, OR (US)

(73) Assignee: INTEL CORPORATION, Santa Clara, CA (US)

(21) Appl. No.: 16/143,816

(22) Filed: Sep. 27, 2018

(51) Int. Cl. G11C 11/16; H01L 43/10; H01L 43/08; H01L 27/22

(52) U.S. Cl. CPC G11C 11/161; H01L 27/228; H01L 43/08; H01L 43/10

(57) ABSTRACT

A magnetic tunnel junction (MTJ) for use in a magnetic spin orbit torque random access memory device (SOT MRAM) is described. Magnetic tunnel junctions described herein include a multi-magnet free layer over a spin orbit torque electrode. The multi-magnet free layer includes at least three sub-layers: a first magnetic sub-layer in direct contact with the SOT electrode having a first magnetic stability, a second magnetic sub-layer having a second magnetic stability greater than the first magnetic stability, and a magnetic coupling layer between the first and second sub-layers.

### BACKGROUND

Integration of non-volatile memory cells on a same substrate as logic transistors is often referred to as “embedded non-volatile memory” or “eNVM.” Embedding non-volatile memory on a same substrate as logic transistors improves computational speed and efficiency compared to memory devices and semiconductor devices that are disposed on separate substrates and that therefore communicate through an inter-substrate bus. While common types of integrated memory devices include eDRAM and SRAM, various types of resistive and magneto-resistive random access memory (RRAM and MRAM, respectively) devices are of increasing interest, particularly for embedded non-volatile memory devices.

Generally, MRAM devices store a bit of data based on a magnetization orientation of a “free” layer of a magneto-resistive device. The electrical resistance depends on the relative magnetic orientation of the free layer relative to an associated magnetized “fixed” or “reference” layer. This resistance state is then used to determine a binary value of “1” or “0” in the MRAM device. Because resistive data storage does not require periodic electrical refreshment, as do memory storage devices that use an electrical charge such as eDRAM and SRAM, the data stored in the MRAM device persists even after power is removed from the circuit. Examples of MRAM memory devices include, but are not limited to, spin orbit torque MRAM (SOT MRAM), a subset of which is spin Hall effect magnetic random access memory (SHE-MRAM), and spin transfer torque MRAM (STT-MRAM).

### BRIEF DESCRIPTION OF THE DRAWINGS

FIG. 1A is a perspective view illustration of an MRAM device having a multi-magnet free layer, in accordance with some embodiments of the present disclosure.

FIG. 1B is an illustration of spin polarization in a spin polarizing electrode in direct contact with one magnetic sub-layer of a multi-magnet free layer of an MRAM device, in accordance with some embodiments of the present disclosure.

FIG. 2 is an illustration of a free layer of a multi-magnet free layer of an MRAM device in which each of the ferromagnetic sub-layers is fabricated from alternating layers of ferromagnetic and non-ferromagnetic materials, in accordance with some embodiments of the present disclosure.

FIG. 3 depicts tunneling magnetoresistance (TMR) versus thickness of a multi-magnet free layer in an MRAM device, in accordance with some embodiments of the present disclosure.

FIG. 4 illustrates a computing system implemented with integrated circuit structures and/or transistor devices formed using the techniques disclosed herein, in accordance with some embodiments of the present disclosure.

The figures depict various embodiments of the present disclosure for purposes of illustration only.

Numerous variations, configurations, and other embodiments will be apparent from the following detailed discussion. Furthermore, as will be appreciated, the figures are not necessarily drawn to scale or intended to limit the described embodiments to the specific configurations shown. For instance, while some figures generally indicate straight lines, right angles, and smooth surfaces, an actual implementation of the disclosed techniques may have less than perfect straight lines and right angles, and some features may have surface topography or otherwise be non-smooth, given real-world limitations of fabrication processes. In short, the figures are provided merely to show example structures.

### DETAILED DESCRIPTION

Techniques are disclosed for forming a magnetic tunnel junction (MTJ) for use in a magnetic spin orbit torque random access memory (SOT MRAM) device. Magnetic tunnel junctions described herein include a multi-magnet free layer over a spin orbit torque (SOT) electrode. The multi-magnet free layer includes at least three sub-layers: a first magnetic sub-layer having a first magnetic stability and that is in direct contact with the SOT electrode, a second magnetic sub-layer having a second magnetic stability greater than the first magnetic stability, and a magnetic coupling layer between the first and second sub-layers. Spin polarization in the SOT electrode can be used to apply torque to the first sub-layer of the multi-magnet free layer. Because the first sub-layer has a low magnetic stability (which is a function of the product of the magnetic anisotropy in the magnetic moment of the domain), the direction of magnetization (equivalently referred to as spin polarization) can be switched with relatively low applied torque from the SOT electrode. The switching of the polarization of the first-sub layer can induce a switch in polarization of the second magnetic sub-layer having a greater magnetic stability. This is due in part from the magnetic coupling of the first sub-layer and the second sub-layer via the magnetic coupling layer which enhances the perpendicular magnetic anisotropy between the first and second sub-layers. In this way, the magnetization of the MTJ can be switched efficiently with relatively low electrode current through the SOT electrode while allowing for long term storage of data (i.e., magnetization polarization) in the second, more magnetically stable, sub-layer.

General Overview

As indicated above, an MTJ MRAM can store a bit of data using a relative resistance between a magnetized free layer and a magnetized reference layer. The magnetization of the free layer can be “switched” to have a low resistance or a high resistance relative to the reference layer. For example, when magnetization of both the free layer and the fixed layer are in the same direction, the MTJ is in a low resistance state. When the magnetization of the free layer and the fixed layer are in opposite directions, the MTJ is in a high resistance state. As mentioned above the high and low resistance states can be associated with the digital binary values of “1” and “0.” MTJs (and thus the associated memory devices) are often configured to use one of two magnetic phenomena to switch magnetization of a free layer (and thus change the resistive state of the MTJ): spin torque transfer (“STT”) or spin orbit torque (SOT), also known as spin orbit coupling (“SOC”). Spin orbit torque is exhibited more specifically through the spin Hall effect (SHE), among other phenomena.

The STT effect can be used to switch devices (e.g., between low resistance and high resistance states) by providing an electrical current directly to a first magnetic domain in a device. The electrons in the provided electrical current become spin polarized according to the magnetization in the first magnetic domain. When flowing into a different magnetic domain, the spin polarized electrons transfer momentum corresponding to the spin polarization of the first domain to the electrons within the different magnetic domain. As more momentum is transferred, the magnetic polarization of the different domain eventually switches to match that of the incoming polarized electrons (and the first domain).

Rather than transferring moment between electrons using a directly applied spin-polarized current as in the STT effect, SOT induces a switch in magnetic polarization by using an electrode in which electrons of opposite spin migrate to opposite lateral surfaces of the electrode. In some examples, this is accomplished by using a material for the electrode that exhibits the spin Hall effect (SHE), although other mechanisms may cause this lateral spin polarization with in the electrode. Regardless of the mechanism, torque from the electrons at the lateral surface in contact with the free layer is transferred to the electrons of the free layer. This effect can be used to switch magnetization of an MTJ device (e.g., change a magnetization of a free layer in an MTJ).

The use of SOT (equivalently SOC) devices in non-volatile memory is of interest, not least for the reason that it is possible to design an SOT MRAM to have better device reliability than other types of MRAM. For example, direct application of electrical current to the layers of an STT MRAM device (and/or the heat generated) can cause degradation of the layers of the material in the MRAM, leading to device reliability issues. Because SOC devices induce a magnetization switch in the free layer by applying a current to an electrode and not directly to the layers of the MRAM, SOC devices are generally more reliable than STT devices. However, SOT devices can sometimes require relatively high currents to produce sufficient torque in the electrode to induce a switch in magnetization of the free layer. Furthermore, the selection of material for the various layers of an SOC device can be limited because SOC MTJ devices generally require direct contact (or indirect contact via a 1-2 nm thick layer of spin-transparent material) between a magnetic free layer and an SOC generating electrode. This configuration generally excludes the addition of layers can provide additional stability and/or reliability in an STT device by increasing interfacial magnetic anisotropy between the free and reference layers.

Thus, techniques are described herein for fabricating SOT MRAM nonvolatile memory devices that can be switched with relatively low electrical current. This is due, at least in part, to SOT MRAM memory devices of the present disclosure including a multi-magnet free layer. A first sub-layer of the multi-magnet free layer is in direct contact with an SOT electrode. This first sub-layer has a first magnetic stability (e.g., proportional to the product of the magnetic anisotropy and domain magnetic moment) that is low and can be efficiently switched by spin polarization in the SOT electrode. A second sub-layer has a second magnetic stability greater than the first magnetic stability, and which requires more energy to switch than that of the first layer. The cooperation of the first sub-layer and the second sub-layer thus provide efficient switching and non-volatile data storage. A magnetic coupling layer is disposed between the first sub-layer and second sub-layer to increase perpendicular magnetic interfacial anisotropy (PMA) between the first and second sub-layers. Because the first sub-layer and the second sub-layer are magnetically coupled via the magnetic coupling layer, the higher magnetic stability second sub-layer changes magnetization upon a switch in magnetization of the first sub-layer. This is sometimes referred to herein as a “two-step” magnetization switch, with the first sub-layer being switched by the SOT electrode and the second sub-layer being subsequently switched by the first sub-layer.

Methodology and Architecture

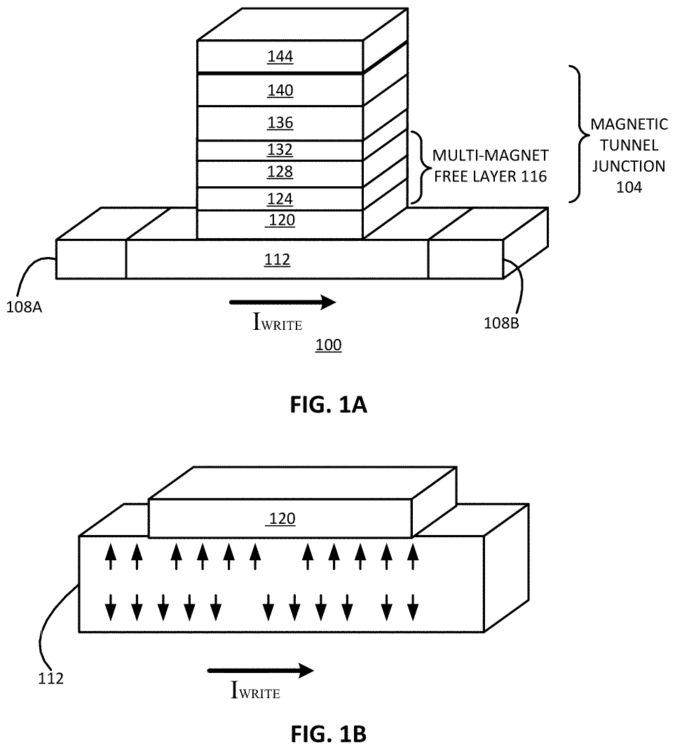

FIG. 1A illustrates one example embodiment of a magnetic tunnel junction (MTJ) device 100, one component of which is a multi-magnet free layer. The example MTJ 100 device includes a magnetic tunnel junction 104, first electrodes 108A, 108B, and an SOT (also referred to as a spin polarizing) electrode 112. The magnetic tunnel junction 104 includes a multi-magnet free layer 116, a tunnel barrier 132, a reference layer 136, a synthetic antiferromagnetic layer 140, and a second electrode 144.

The first electrodes 108A, 108B provide an electrical current (shown by an arrow in FIG. 1A labeled “I_{WRITE}”) to the MTJ device 100, and more specifically to the spin polarizing electrode 112. The first electrodes 108A, 108B can include any conductive material such as, but not limited to, copper, aluminum, and other materials commonly used for conductive interconnections in integrated circuits (e.g., Ta, TaN, TiN). In some examples, the first electrodes 108A, 108B can be fabricated using single damascene or dual damascene processes commonly used in integrated circuit interconnect technology. For example, a trench can be etched into an interlayer dielectric layer (e.g., SiO₂) and filled by one or more layers of a liner (SiN, TaN) and/or a conductive material. The first electrodes 108A, 108B are in electrical contact with the spin polarizing electrode 112. In this context, “electrical contact” simply indicates that current can pass from one of electrodes 108A, 108B through the spin polarizing electrode 112 to the other one of electrodes 108A, 108B. This electrical contact can include direct contact between each of the electrodes 108A, 108B, 112, as well as indirect contact through intervening conductive layers (not shown).

The spin polarizing electrode 112 is fabricated from a spin polarizing material that causes electrons in the current I_{WRITE} applied to the spin polarizing electrode 112 by first electrodes 108A, 108B to diffuse to opposing lateral surfaces of the spin polarizing electrode 112 based on the polarity of their spin. This is indicated in FIG. 1B, where polarization of “spin up” electrons at a “top” surface in direct contact with the first sub-layer 120 of the multi-magnet free layer 116 (described below) are indicated by arrows in a first direction. The polarization of “spin down” electrons and an opposing surface is indicated by arrows in day second direction antiparallel to the first direction.

In some examples, the spin polarization that occurs in the spin polarizing electrode 112 occurs via phenomena such as the spin Hall effect (SHE). As indicated above, the spin polarization within the spin polarizing electrode 112 can exert a torque on electrons within the sub-layer 120. This torque is produced via magnetic dipole coupling, the force of which is proportional to the saturation magnetization of the ferromagnetic first and second sub-layers 120, 128 of the free layer 116. The transfer of this torque can cause the magnetization of the sub-layer 120 to switch polarity from spin up to spin down, or vice versa. It will be appreciated that an externally applied magnetic field and/or a directly applied supplemental spin transfer torque (STT) current can be used to the supplement torque exerted by the spin polarizing electrode 112 on the sub-layer 120.

The spin polarizing electrode 112 may be any material suitable to generate spin orbit torque and can include, but not limited to, β phase Ta, β phase W, Pt, and Co or multilayers or alloys of the previously listed materials. In some embodiments, the spin polarizing electrode 112 can have a thickness of from 2 nm and 20 nm.

As indicated above, the multi-magnet free layer 116 includes three sub-layers: a first sub-layer 120, a second sub-layer 128, and a third sub-layer 124 between the first sub-layer 120 and the second sub-layer 128. Each of these sub-layers is described in turn below.

As described above, the first sub-layer 120 (a first side of which is in direct contact with the spin polarizing electrode 112) has a first magnetic stability (which is calculated as a product of volume (V) and anisotropy energy (Ku) that is less than the second magnetic stability of the second sub-layer 128. For this reason, the first sub-layer 120 can be switched (i.e., its direction of magnetization can be changed from spin up to spin down, or vice versa) with less energy than layers with a higher magnetic stability (e.g., the second sub-layer 128). Upon a change in the direction of magnetization of the first sub-layer 120 (e.g., caused in part by a spin orbit coupling with the spin the polarizing electrode 112), the direction of magnetization of the second sub-layer 128 can be switched more efficiently (e.g., at lower currents) than by directly switching the magnetization of the second sub-layer 128 directly. This in effect produces a two-step switching of the magnetization of the MTJ MRAM device 100, where the lower magnetic stability first sub-layer 120 switched first, which then causes a second switching of the higher magnetic stability second sub-layer 128. As described below, the presence of the second sub-layer 128 in the MTJ 104 having a higher magnetic stability than the first sub-layer 120 improves the ability of the MTJ memory device 100 to store data.

The first sub-layer 120 can be fabricated from ferromagnetic materials including, but not limited to, cobalt iron (CoFe) or cobalt iron boron (CoFeB). In some embodiments, the first sub-layer 120 (as well as any other permanent magnetic layer described herein) can include iron and one or more of cobalt or boron in any desirable ratio. In some examples, the first sub-layer 120 (as well as other permanent magnet layers described herein) may also include W, Ta, any may further include multilayer assemblies thereof. The ferromagnetic material of the first sub-layer 120 can be deposited using any of a variety of techniques including, but not limited to, epitaxial deposition, atomic layer deposition, chemical vapor deposition (CVD), and sputtering, among others. While an epitaxial interface between the various sub-layers of the free layer 116 and the other elements of the device 100 can improve performance of the device (e.g., by increasing perpendicular magnetic anisotropy), it is not necessary.

In some examples, a first thickness of the first sub-layer 120 is 3 nm or less. In one example, the first thickness of the first sub-layer 120 is less than that of the second sub-layer 128 so that the first sub-layer 120 is easier to switch (having a lower magnetic stability due in part to its thinner configuration, although this is not required. In other examples, sub-layer 120 can be thicker than second sub-layer 128 to produce a magnetic stability of first layer less than that of the second sub-layer 128.

The second sub-layer 128 layer may consist of single or multilayer materials such as those described above in the context of the first sub-layer 120. However, the composition of the second sub-layer 128 can be formulated so as to have a higher magnetic stability than that of the first sub-layer 124. Alternatively, the physical configuration (e.g., thickness) of the second sub-layer 128 can be greater than the first sub-layer 120 so that the magnetic stability of the second sub-layer 128 is greater than the magnetic stability of the first sub-layer 120. In some examples, a second thickness of the first sub-layer 120 is 3 nm or less. The second sub-layer 128 can be formed using any of the techniques described above in the context of the first sub-layer 120.

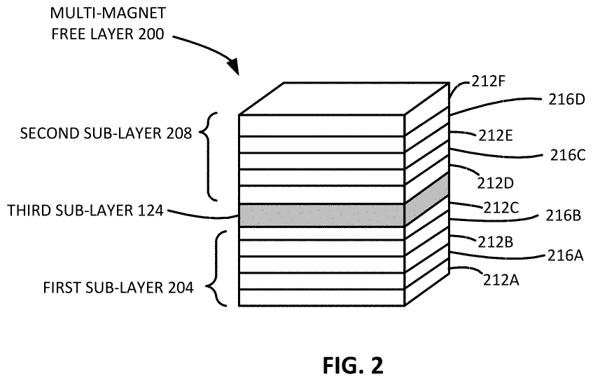

It will be appreciated that while the first sub-layer 120 and second sub-layer 128 are both shown in FIG. 1A as single layers, this need not be the case. FIG. 2 illustrates an alternative embodiment of a multi-magnet free layer 200 in which a first sub-layer 204 and a second sub-layer 208 are composed of multiple layers. In some example, both the first sub-layer 204 and the second sub-layer 208 can include alternating layers of a ferromagnetic material 212A-212F (generically, 212) and a non-magnetic layer 216A-216D (generically, 216). In some examples, both the first sub-layer 204 and the second sub-layer 208 can also include alternating layers of ferromagnetic materials including, but not limited to, alternating layers of cobalt and nickel. This alternating layer structure can increase magnetic anisotropy compared to the anisotropy of a sub-layer composed only from a single ferromagnetic material (e.g., as shown in FIG. 1A). In some examples, the number of layers within one or both of the first sub-layer 204 and the second sub-layer 208 can range from at least 2 to 10 layers of the magnetic material 212 and non-magnetic material 216. The ferromagnetic material 212 can include any of the materials or combinations of materials previously described in the context of FIG. 1A. The non-magnetic material 216 may include a metal such as platinum, tungsten, palladium or iridium. Examples of thicknesses of the magnetic layer 212 and the non-magnetic layer 216 range from 0.05 nm to 0.3 nm. In examples such as the one depicted in FIG. 2, a magnetic material layer 212A of the first sub-layer 204 is directly adjacent to and in contact with the spin polarizing electrode 112 and a magnetic material layer 212C is in contact with the third sub-layer 124. Analogously, magnetic layers 212D and 212F of the second sub-layer 208 are in contact with the third sub-layer 124 and the tunnel barrier 132 (shown in FIG. 1).

Another element of the multi-magnet free layer 116 is the third sub-layer 124, disposed between the first sub-layer 120 and the second sub-layer 128. The third sub-layer 124 is a non-magnetic material that increases the perpendicular magnetic anisotropy (sometimes abbreviated as PMA) between the first sub-layer 120 and the second sub-layer 128. This increase in PMA caused by the third sub-layer has a number of functions. In some examples, increased PMA between the first sub-layer 120 and the second sub-layer 128 increases magnetic coupling between these layers, which further facilitates switching of the more magnetically stable second sub-layer 128 in response to a change in magnetization of the less magnetically stable first sub-layer 120. In some examples, third sub-layer 124 and its increase in PMA can also increase the stability of magnetization in the second sub-layer 128. That is, because of the increase in PMA the magnetization of the second sub-layer 128 is less likely to unintentionally switch in response to thermal stimuli, while still retaining the ability to be switched efficiently by the magnetically coupled first sub-layer 120.

In some examples, the third sub-layer 124 comprises magnesium and oxygen and can be less than 1 nm thick. In some examples, the third sub-layer 124 can also be comprised of: aluminum and oxygen; tantalum, oxygen and magnesium; and aluminum and oxygen.

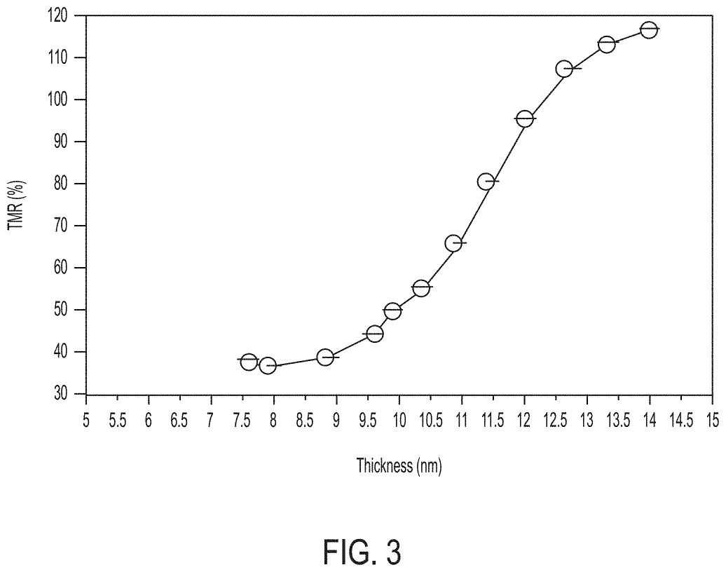

Returning to FIG. 1A, a tunnel barrier 132 is in contact with the second sub-layer 128 on a side of the second sub-layer 128 opposite the third sub-layer 124. The tunnel barrier 132 can be composed of the same material as the third sub-layer 124, thus causing an increase in the PMA of the second sub-layer 128 by “sandwiching” the second sub-layer 128 on two opposing surfaces with PMA-enhancing materials. This “dual MgO” interface on opposing faces of the second sub-layer 128 can further increase the PMA of the second sub-layer 128 relative to the first sub-layer 120 due to interfacial anisotropy caused by hybridization between iron and oxygen at an interface between sub-layers 128 and 124. Furthermore, the addition of the tunnel barrier 132 increases the magnetic dipole coupling with the first sub-layer 120 and the magnetic stability of the second sub-layer 128. As described below in the context of FIG. 3, this configuration can also increase the tunneling magnetoresistance (TMR) of the MTJ device 100 as a whole.

The tunnel barrier 132 (sometimes referred to as a “barrier layer” or a “spin filter”) is generally a dielectric material that selectively permits electrons having a spin polarization matching that of the multi-magnet free layer 116 to tunnel between the reference layer 136 and multi-magnet free layer 116 while decreasing a rate at which electrons having an opposite spin can tunnel between these layers. This selective tunneling can be used to control the magnetization polarity of electrons in the multi-magnet free layer 136, and thus control the resistance of the MTJ device 100.

In some examples the tunnel barrier 132 is fabricated from oxygen and at least one of magnesium (e.g., MgO) or aluminum (e.g., Al₂O₃) although other dielectric materials may also be used. The tunnel barrier 132 can be deposited using any of a variety of techniques including, but not limited to chemical vapor deposition, organometallic chemical vapor deposition, atomic layer deposition, sputtering, among other deposition techniques. In some embodiments, the tunnel barrier 132 is epitaxially matched with the second sub-layer 128 of the multi-magnet free layer 116 and/or the reference layer 136 (described below). In some embodiments, epitaxial matching includes similarly oriented single crystals in both layers (e.g., confronting (001) planes) that differ in lattice parameter by less than 2% or less than 1%. In some examples, epitaxially matched second sub-layer 128, tunnel barrier 132, and reference layer 136 can increase a tunneling magnetoresistance

(TMR) ratio in the MTJ device 100, as described below in more detail. In some example, the tunnel barrier 132 can have a thickness of from 0.5 nm to 2 nm.

The reference layer 136 can, in some examples, be fabricated from a material or a stack of materials that maintains a magnetic polarity (i.e., a spin of electrons) and is a “hard” magnetic material having a magnetic coercivity and/or magnetic anisotropy higher than that of the multi-magnet free layer 116. Types of materials used to fabricate the reference layer 136 include permanent magnetic materials, such as ferromagnetic materials. In one example, the reference layer 136 is fabricated from a single layer of cobalt iron boron (CoFeB). In another example, the reference layer 136 is composed of a stack of materials that includes a cobalt iron boron (CoFeB) layer, a ruthenium (Ru) layer, and another cobalt iron boron (CoFeB) layer. The reference layer 136 can be deposited using any of a variety of techniques including, but not limited to, chemical vapor deposition, atomic layer deposition, sputtering, among other deposition techniques. As indicated above, in some cases the reference layer 136 is epitaxial with the adjacent tunnel barrier 132. In some embodiments, the reference layer 136 can have a thickness from 1 nm to 5 nm.

The total combined thickness of the multilayer stack that includes the first, second, and third sub-layers may range between 2.5 nm and 6 nm.

The example MTJ device 100 also includes a synthetic antiferromagnetic (SAF) structure 140 (sometimes referred to as a that can be disposed between a second electrode 144 and the reference layer 136. In some examples the SAF structure 140 is included to reduce the likelihood of unintentional switching of the magnetization of the reference layer 136. In some examples, the SAF structure 140 includes a non-magnetic layer sandwiched between a first ferromagnet and a second ferromagnet. The first ferromagnet and the second ferromagnet are antiferromagnetically coupled to each other. In an embodiment, the first and second ferromagnets can include layer of a magnetic metal such as iron or cobalt separated by a layer of a non-magnetic metal including but not limited to Co/Pd or a Co/Pt. In an embodiment, the non-magnetic layer includes a ruthenium or an iridium layer. In various examples, each of the layers within the SAF structure 140 can be from 1 nm to 5 nm thick. Other examples of SAF structures 140 may also be included, as will be apparent.

The MTJ device 100 also includes a second electrode 144 on the SAF structure 140. In an embodiment, the second electrode 144 includes any material appropriate for use in the first electrodes 108A, 1008B such as copper, aluminum, Ta, TaN, or TiN. In an embodiment, the electrode 144 has a thickness between 5 nm and 70 nm.

It will be appreciated that the example MTJ device 100 (and variations which will be clear in light of the present disclosure) can be fabricated on a substrate (not shown). Substrates of semiconductor materials enable the fabrication of various other components useful for the control and integration of MTJ memory devices, such as the device 100. These components include access transistors, word lines, bit lines, as well as integrated circuits that use data stored in the MTJ memory device 100 (e.g., random logic transistors).

Substrates on which MTJ MRAMs of the present disclosure can be fabricated may include: a bulk substrate including group IV semiconductor material, such as silicon (Si), germanium (Ge), or silicon germanium (SiGe), and/or any other suitable semiconductor material(s); an X on insulator (XOI) structure where X includes group IV material (and/or other suitable semiconductor material) and the insulator material is an oxide material or dielectric material or some other electrically insulating material; or some other suitable multilayer structure where the top layer includes group IV material and/or other suitable semiconductor material. The use of “group IV semiconductor material” (or “group IV material” or generally, “IV”) herein includes at least one group IV element (e.g., silicon, germanium, carbon, tin, lead), such as Si, Ge, SiGe, and so forth. Note that group IV may also be known as the carbon group or IUPAC group 14, for example. In some embodiments, a substrate may include a surface crystalline orientation described by a Miller Index plane of (001), (011), or (111), for example, as will be apparent in light of this disclosure. Substrates may have a thickness in the range of 50 to 950 microns, for example, or any other suitable thickness that will be apparent in light of this disclosure. However, in embodiments where substrate is just a top layer of a multilayer substrate structure, that top layer need not be so thick and may be relatively thinner, such as having a thickness in the range of 20 nm to 10 microns, for example. In some embodiments, substrate may be used for one or more other integrated circuit (IC) devices, such as various diodes (e.g., light-emitting diodes (LEDs) or laser diodes), various transistors (e.g., MOSFETs or TFETs), various capacitors (e.g., MOSCAPs), various microelectromechanical systems (MEMS), various nanoelectromechanical systems (NEMS), various sensors, and/or any other suitable semiconductor or IC devices, depending on the end use or target application. Accordingly, in some embodiments, the transistor structures may be included in a system-on-chip (SoC) application used to access, write to, read from, or otherwise process data stored in a MTJ MRAM of the present disclosure, as will be apparent in light of this disclosure.

For examples of the substrate that are an XOI configuration, the insulation can be fabricated from any of a number of insulator materials or semi-insulator materials used for electrical insulation zo in an interconnect layer of an integrated circuit. These insulator materials include, for instance, nitrides (e.g., Si₃N₄), oxides (e.g., SiO₂, Al₂O₃, AlSiOₓ), oxynitrides (e.g., SiOₓN_{y}), carbides (e.g., SiC), oxycarbides, polymers, silanes, siloxanes, or other suitable insulator materials. In some embodiments, the substrate can be implemented with ultra-low-k insulator materials, low-k dielectric materials, or high-k dielectric materials depending on the application. Example low-k and ultra-low-k dielectric materials include porous silicon dioxide, carbon doped oxide (CDO), organic polymers such as perfluorocyclobutane or polytetrafluoroethylene, fluorosilicate glass (FSG), and organosilicates such as silsesquioxane, siloxane, or organosilicate glass. Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

Tunneling Magneto Resistance

Tunneling magneto resistance (TMR) is a useful parameter in determining suitability of a MTJ for use in MRAM because it indicates the electrical resistance between a free layer and a fixed (or reference) layer in an MTJ. The greater the resistance between the two layers, the more easily the resistance can be measured and thus the more accurate and reliable the data storage. TMR is a ratio of a difference between an antiparallel magnetization resistance (e.g., a high resistance state) and a parallel magnetization resistance (a low resistance state) divided by the low resistance state. One representation of this is shown in Equation 1.

TMR=[(Antiparallel Resistance−Parallel Resistance)]/Parallel resistance]×100 Eq. 1

FIG. 3 depicts experimental results of an SOT MRAM measuring the TMR as a function of thickness of a multi-magnet free layer, and more specifically as a function of the variation in thickness of a second magnetic sub-layer of a multi-magnet free layer.

In the example measured, the multi-magnet free layer had a first sub-layer 1 nm thick that was composed of CoFeB. The third sub-layer was between 0.7 nm and 0.9 nm thick and composed of MgO. The second sub-layer was actually composed of three constituent layers, as shown and described in the context of FIG. 2. The second sub-layer included a first ferromagnetic layer in contact with the third sub-layer composed of CoFeB. This first ferromagnetic layer was 0.6 nm thick. A non-magnetic layer of tungsten 0.3 nm thick was placed on a side of the first ferromagnetic layer opposite that of the MgO layer. A second ferromagnetic layer of the second sub-layer was disposed on the opposite side of the non-magnetic layer of tungsten and was also composed of CoFeB. FIG. 3 illustrates TMR (measured using current in plane tunneling or “CIPT” characterization) as a function of increasing thickness of the second ferromagnetic layer of the second sub-layer.

As shown, upon a thickness of approximately 12 nm of the second ferromagnetic layer of the second sub-layer, TMR of the multi-magnet free layer is increased at least 100%. This is suggestive that, as indicated above, increasing a thickness of the second sub-layer increases the stability of the layer and thus the ability to determine a difference in magnetization direction (and thus electrical resistance) between the first sub-layer and the second sub-layer. Furthermore, it can be seen from the graph that the rate of increase (i.e., the slope of the graph) is greater than one and thus some regimes of thickness disproportionately produce the increase in TMR.

Example System

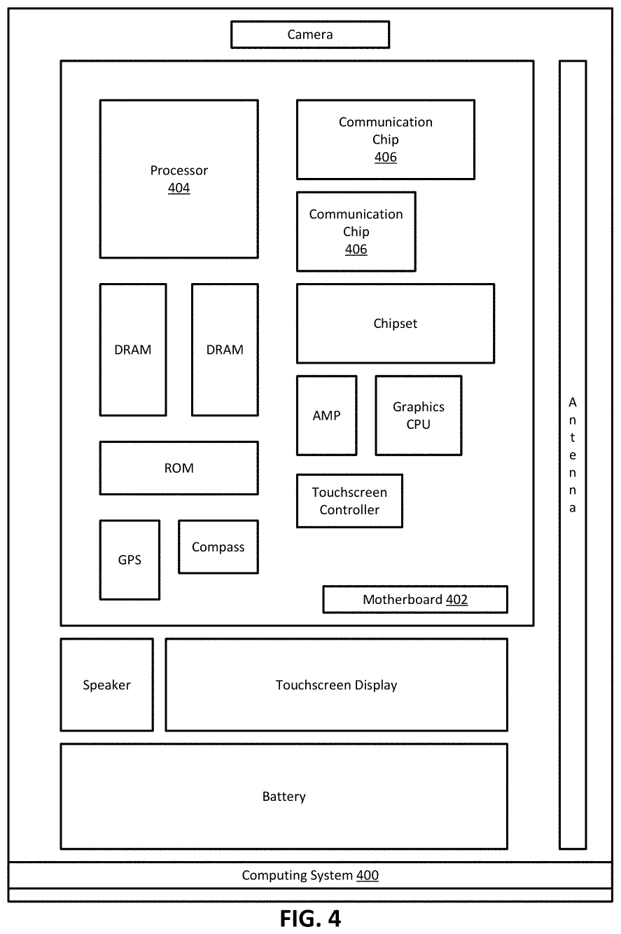

FIG. 4 is an example computing system implemented with one or more of the integrated circuit structures as disclosed herein, in accordance with some embodiments of the present disclosure. As can be seen, the computing system 400 houses a motherboard 402. The motherboard 402 may include a number of components, including, but not limited to, a processor 404 and at least one communication chip 406, each of which can be physically and electrically coupled to the motherboard 402, or otherwise integrated therein. As will be appreciated, the motherboard 402 may be, for example, any printed circuit board, whether a main board, a daughterboard mounted on a main board, or the only board of system 400, etc.

Depending on its applications, computing system 400 may include one or more other components that may or may not be physically and electrically coupled to the motherboard 402. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 400 may include one or more integrated circuit structures or devices configured in accordance with an example embodiment (e.g., to include one or more MTJ memory devices that include a multi-magnet free layer, as variously provided herein). In some embodiments, multiple functions can be integrated into one or more chips (e.g., for instance, note that the communication chip 406 can be part of or otherwise integrated into the processor 404).

The communication chip 406 enables wireless communications for the transfer of data to and from the computing system 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 406 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 400 may include a plurality of communication chips 406. For instance, a first communication chip 406 may be dedicated to shorter range wireless communications such as Wi-Fi and Bluetooth and a second communication chip 406 may be dedicated to longer range wireless communications such as GPS, EDGE, GPRS, CDMA, WiMAX, LTE, Ev-DO, and others. In some embodiments, communication chip 406 may include one or more transistor structures having a gate stack an access region polarization layer as variously described herein.

The processor 404 of the computing system 400 includes an integrated circuit die packaged within the processor 404. In some embodiments, the integrated circuit die of the processor includes onboard circuitry that is implemented with one or more integrated circuit structures or devices as variously described herein. The term “processor” may refer to any device or portion of a device that processes, for instance, electronic data from registers and/or memory to transform that electronic data into other electronic data that may be stored in registers and/or memory.

The communication chip 406 also may include an integrated circuit die packaged within the communication chip 406. In accordance with some such example embodiments, the integrated circuit die of the communication chip includes one or more integrated circuit structures or devices as variously described herein. As will be appreciated in light of this disclosure, note that multi-standard wireless capability may be integrated directly into the processor 404 (e.g., where functionality of any chips 406 is integrated into processor 404, rather than having separate communication chips). Further note that processor 404 may be a chip set having such wireless capability. In short, any number of processor 404 and/or communication chips 406 can be used. Likewise, any one chip or chip set can have multiple functions integrated therein.

In various implementations, the computing system 400 may be a laptop, a netbook, a zo notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

Further Example Embodiments

The following examples pertain to further embodiments, from which numerous permutations and configurations will be apparent.

Example 1 is a magnetic memory cell comprising: a first electrode; a multi-magnet free magnetic layer comprising a first sub-layer comprising a first ferromagnetic material having a first magnetic stability, the first sub-layer in direct contact with the first electrode; a second sub-layer comprising second ferromagnetic material having a second magnetic stability greater than the first magnetic stability; a third sub-layer between the first sub-layer and the second sub-layer comprising a magnetic coupling material; a reference magnetic layer over the multi-magnet free magnetic layer; and a second electrode over the reference magnetic layer on a side of the reference magnetic layer opposite the multi-magnet free magnetic layer.

Example 2 includes the subject matter of Example 1, wherein the first electrode comprises a first portion of one or more of β phase Ta, β phase W, Pt, and Co in direct contact with the first sub-layer.

Example 3 includes the subject matter of Example 1 or 2, wherein the first electrode further comprises a second portion, and a third portion on opposing sides of the first portion, wherein the second portion and the third portion comprise one or more of copper, aluminum, tantalum, and titanium.

Example 4 includes the subject matter of any of the preceding Examples, wherein the first ferromagnetic material and the second ferromagnetic material are the same.

Example 5 includes the subject matter of any of the preceding Examples, wherein the first ferromagnetic material and the second ferromagnetic material comprise iron and at least one of cobalt or boron.

Example 6 includes the subject matter of any of the preceding Examples, wherein the first sub-layer has a first thickness and the second sub-layer has a second thickness greater than the first thickness.

Example 7 includes the subject matter of Example 6, wherein the first thickness is less than 3 nm.

Example 8 includes the subject matter of Example 6, wherein the first thickness is from 1 nm to 2 nm.

Example 9 includes the subject matter of any of Examples 1-5, 7, 8, wherein the second thickness is greater than the first thickness.

Example 10 includes the subject matter of any of the preceding Examples, wherein the multi-magnet free magnetic layer is from 2.5 nm to 6 nm thick.

Example 11 includes the subject matter of any of the preceding Examples, wherein the third sub-layer comprises magnesium and oxygen.

Example 12 includes the subject matter of any of the preceding Examples, wherein the third sub-layer has a third thickness of less than 1 nm.

Example 13 includes the subject matter of any of the preceding Examples, wherein the reference magnetic layer comprises a permanent magnet comprising iron and one or more of cobalt and boron.

Example 14 includes the subject matter of any of the preceding Examples, further comprising a tunnel barrier layer comprising magnesium and oxygen, the tunnel barrier layer in direct contact with the second sub-layer of the multi-magnet free magnetic layer on a side of the second sub-layer opposite the third sub-layer.

Example 15 includes the subject matter of any of the preceding Examples, further comprising a synthetic antiferromagnet (SAF) layer over the reference magnetic layer.

Example 16 includes the subject matter of Example 15, wherein the synthetic antiferromagnet layer comprises: a first SAF sub-layer comprising a ferromagnet having a first magnetization direction; a second SAF sub-layer comprising a ferromagnet having a second magnetization direction opposite the first magnetization direction; and a third SAF sub-layer between the first SAF sub-layer and the second SAF sub-layer, the third SAF sub-layer comprising one or more of ruthenium or iridium.

Example 17 includes the subject matter of any of the preceding Examples, wherein the first sub-layer comprises a plurality of alternating first and second layers, the first alternating layers comprising iron and one or more of cobalt and boron and the second alternating layers comprising one or more platinum, palladium, or iridium.

Example 18 includes the subject matter of Example 17, wherein a thickness of the first alternating layer and a thickness of the second alternating layer is from 0.05 nm to 0.3 nm.

Example 19 includes the subject matter of any of the preceding Examples, wherein a tunneling magneto resistance (TMR) of the multi-magnet free magnetic layer is at least 100% at a thickness of 13 nm.

Example 20 includes the subject matter of any of the preceding Examples, comprising an integrated circuit device comprising the magnetic memory cell of claim 1.

Example 21 includes the subject matter of any of Examples 1-16, 18, wherein the first sub-layer comprises a plurality of alternating first and second layers, the first alternating layers comprising a first ferromagnetic material and a second ferromagnetic material.

Example 22 includes the subject matter of Example 21, wherein the first ferromagnetic material is cobalt and the second ferromagnetic material is iron.

Example 23 includes the subject matter of any of the preceding Examples, wherein the third sub-layer comprises oxygen and at least one of aluminum, tantalum, and magnesium.

What is claimed is:

1. A magnetic memory cell comprising:
a first electrode;
a multi-magnet free magnetic layer comprising
a first sub-layer comprising a first ferromagnetic material having a first magnetic stability, the first sub-layer in direct contact with the first electrode;
a second sub-layer comprising second ferromagnetic material having a second magnetic stability greater than the first magnetic stability;
a third sub-layer between the first sub-layer and the second sub-layer comprising a magnetic coupling material;
a reference magnetic layer over the multi-magnet free magnetic layer; and
a second electrode over the reference magnetic layer on a side of the reference magnetic layer opposite the multi-magnet free magnetic layer.

2. The magnetic memory cell of claim 1, wherein the first electrode comprises a first portion of one or more of β phase Ta, β phase W, Pt, and Co in direct contact with the first sub-layer.

3. The magnetic memory cell of claim 2, wherein the first electrode further comprises a second portion, and a third portion on opposing sides of the first portion, wherein the second portion and the third portion comprise one or more of copper, aluminum, tantalum, and titanium.

4. The magnetic memory cell of claim 1, wherein the first ferromagnetic material and the second ferromagnetic material are the same.

5. The magnetic memory cell of claim 1, wherein the first ferromagnetic material and the second ferromagnetic material comprise iron and at least one of cobalt or boron.

6. The magnetic memory cell of claim 1, wherein the first sub-layer has a first thickness and the second sub-layer has a second thickness greater than the first thickness.

7. The magnetic memory cell of claim 6, wherein the first thickness is less than 3 nm.

8. The magnetic memory cell of claim 6, wherein the first thickness is from 1 nm to 2 nm.

9. The magnetic memory cell of claim 6, wherein the second thickness is greater than the first thickness.

10. The magnetic memory cell of claim 1, wherein the multi-magnet free magnetic layer is from 2.5 nm to 6 nm thick.

11. The magnetic memory cell of claim 1, wherein the third sub-layer comprises magnesium and oxygen.

12. The magnetic memory cell of claim 1, wherein the third sub-layer has a third thickness of less than 1 nm.

13. The magnetic memory cell of claim 1, wherein the reference magnetic layer comprises a permanent magnet comprising iron and one or more of cobalt and boron.

14. The magnetic memory cell of claim 1, further comprising a tunnel barrier layer comprising magnesium and oxygen, the tunnel barrier layer in direct contact with the second sub-layer of the multi-magnet free magnetic layer on a side of the second sub-layer opposite the third sub-layer.

15. The magnetic memory cell of claim 1, further comprising a synthetic antiferromagnet (SAF) layer over the reference magnetic layer. i

[symbol]

16. The magnetic memory cell of claim 15, wherein the synthetic antiferromagnet layer comprises:
a first SAF sub-layer comprising a ferromagnet having a first magnetization direction;
a second SAF sub-layer comprising a ferromagnet having a second magnetization direction opposite the first magnetization direction; and
a third SAF sub-layer between the first SAF sub-layer and the second SAF sub-layer, the third SAF sub-layer comprising one or more of ruthenium or iridium.

17. The magnetic memory cell of claim 1, wherein the first sub-layer comprises a plurality of alternating first and second layers, the first alternating layers comprising iron and one or more of cobalt and boron and the second alternating layers comprising one or more platinum, palladium, or iridium.

18. The magnetic memory cell of claim 17, wherein a thickness of the first alternating layer and a thickness of the second alternating layer is from 0.05 nm to 0.3 nm.

19. The magnetic memory cell of claim 1, wherein a tunneling magneto resistance (TMR) of the multi-magnet free magnetic layer is at least 100% at a thickness of 13 nm.

20. An integrated circuit device comprising the magnetic memory cell of claim 1.
